(19) United States
(12) Patent Application Publication
(10) Pub. No.: US 2013/0112633 A1
(43) Pub. Date: May 9, 2013

(54) RETAINING APPARATUS FOR DATA STORAGE DEVICE

(71) Applicants: YUN-LUNG CHEN, Tu-Cheng (TW); CHUNG CHAI, Tu-Cheng (TW); DA-LONG SUN, Wuhan City (CN); ZHI-MING GUO, Wuhan City (CN)

(72) Inventors: YUN-LUNG CHEN, Tu-Cheng (TW); CHUNG CHAI, Tu-Cheng (TW); DA-LONG SUN, Wuhan City (CN); ZHI-MING GUO, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/526,600

(22) Filed: Jun. 19, 2012

(30) Foreign Application Priority Data
Nov. 8, 2011 (CN) 201110349608.1

(51) Int. Cl. H05K 7/18; H05K 7/20

(52) U.S. Cl. 211/26

(57) ABSTRACT

A retaining apparatus for a data storage device includes a base board, a bracket, and a tray. The bracket is mounted to the base board. A receiving space is defined between the base board and the bracket. The tray is received in the receiving space. The tray includes a pair of mounting members. Each of the pair of mounting members includes a spring and an arm. The spring resiliently abuts against the bracket towards a first direction. The arm resiliently abuts against the bracket towards a second direction. The first direction is substantially perpendicular to the second direction.

### BACKGROUND

1. Technical Field

The disclosure generally relates to a retaining apparatus for data storage devices, especially to a retaining apparatus with a tray for receiving and retaining a data storage device.

2. Description of Related Art

A data storage device, such as a hard disk drive, is directly screwed to a computer chassis. This mounting means can be complex, difficult, and time-consuming during installation. In addition, vibration from other nearby components can be directly transferred to the data storage device through the screws. The data storage device may suffer damage over time from the vibrations. As a result, efforts have been taken to introduce a mounting apparatus for reducing vibration of data storage devices.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a retaining apparatus and a data storage device in one embodiment.

FIG. 2 is an enlarged view of a circled portion II of FIG. 1.

FIG. 3 is a partially assembled view of the retaining apparatus of FIG. 1.

FIG. 4 is an assembled view of the retaining apparatus of FIG. 1.

FIG. 5 is similar to FIG. 4, but the tray is moved into the bracket.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

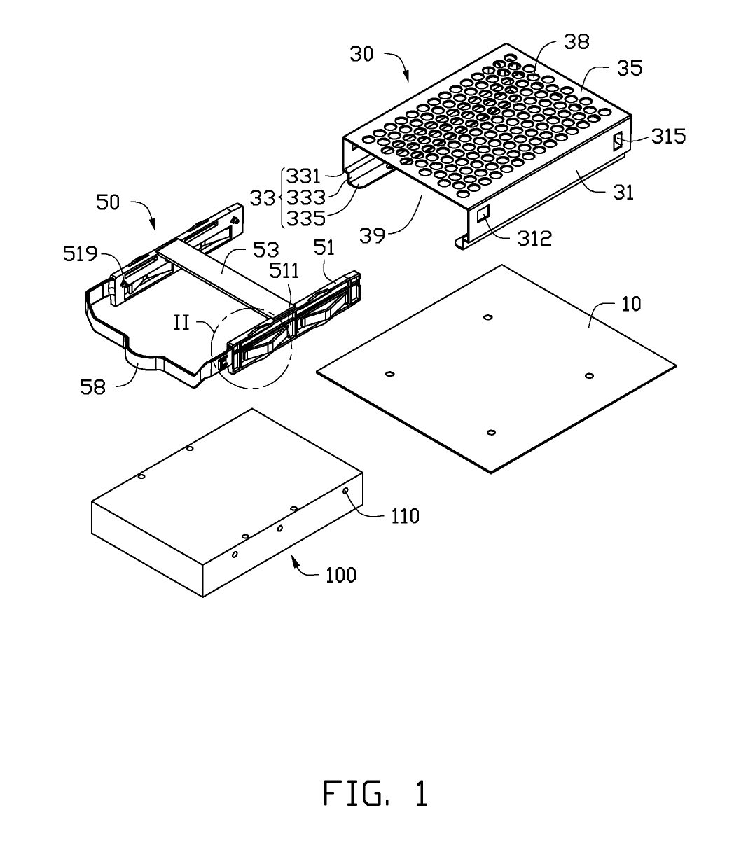

Referring to FIG. 1, in one embodiment, a retaining apparatus includes a base board 10, a bracket 30, and a tray 50. The tray 50 may receive a data storage device 100 and retain the data storage device 100 to the bracket 30 and the base board 10.

The data storage device 100 may be a hard disk drive or a CD-ROM drive. A plurality of mounting holes 110 is defined in the data storage device 100.

The bracket 30 includes a top wall 35, two parallel sidewalls 31, and two retaining portions 33 located at the sidewalls 31. A plurality of heat dissipating holes 38 is defined in the top wall 35. Each of the retaining portions 33 is step like. Each of the retaining portions 33 includes a supporting flange 331, a connecting piece 333, and a mounting piece 335. The supporting flange 331 and the mounting piece 335 are perpendicular to the connecting piece 333. A receiving space 39 is defined by the top wall 35, the two sidewalls 31, and the two retaining portions 33 for receiving the tray 50 and the data storage device 100. A locking hole 312 is defined in each of the sidewalls 31. A stop 315 is located at an inner side of each of the sidewalls 31. The locking hole 312 and the stop 315 are located at opposite sides of each of the sidewalls 31.

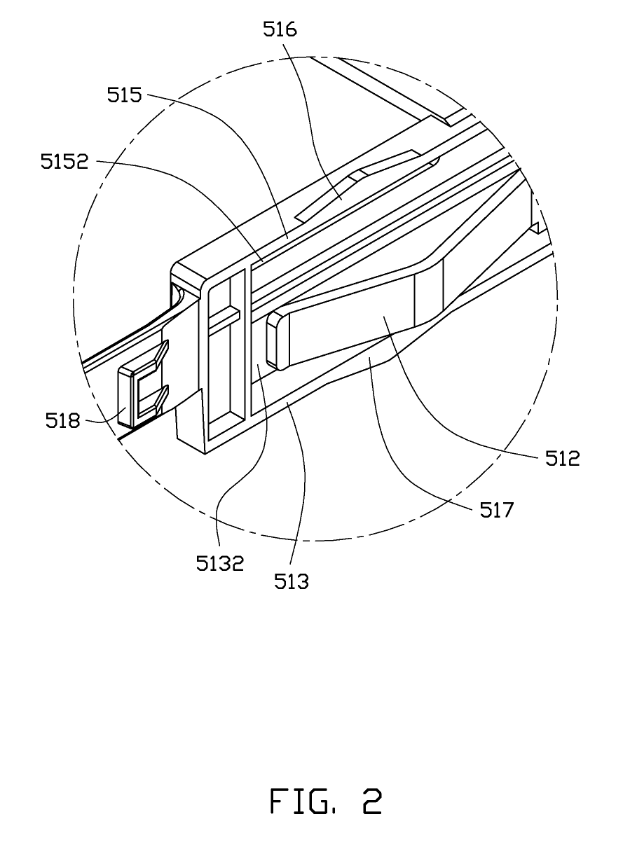

Referring also to FIG. 2, the tray 50 includes a pair of mounting members 51, a handle 58 connected to the pair of mounting members 51, and a bridge 53 connecting to the pair of mounting members 51. Each of the mounting members 51 includes a body 511, two springs 512, a first arm 515, and a second arm 513. Each of the springs 512 includes a free distal end. Each of the springs 512 may be V-shaped or U-shaped. The first arm 515 and the second arm 513 are connected to the body 511 at two opposite ends thereof and are resilient at a middle portion. A first opening 5152 is defined in the body 515 at a bottom side of the first arm 515 for providing a first deformation space for the first arm 515. A second opening 5132 is defined in the body 511 adjacent to the second arm 513 for providing a second deformation space for the second arm 513. The first arm 515 includes a first protrusion 516. The second arm 513 includes a second protrusion 517. The first protrusion 516 and the second protrusion 517 may have an arcuate or triangular configuration. The springs 512 may be respectively located in the second openings 5132. Each of the bodies 511 includes two pins 519 for locking the data storage device 100. Each of the bodies 511 includes a tab 518 adjacent to the handle 58 and the free distal end of a corresponding one of the springs 512.

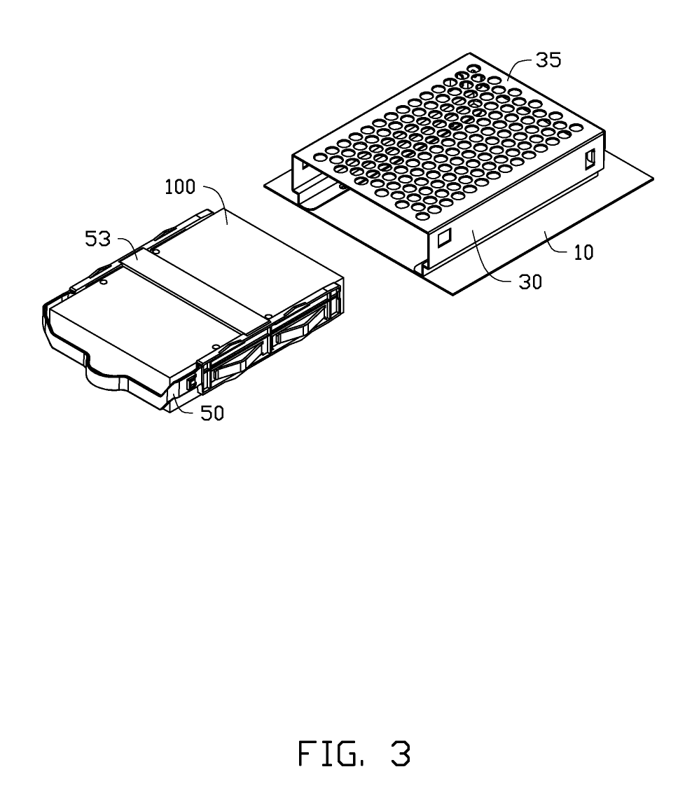

Referring to FIG. 3, in assembly of the bracket 30 and the tray 50, the bracket 30 is mounted to the base board 10. The mounting members 51 are flexed away from each other, and the data storage device 100 is moved into the tray 50. The tray 30 is released and the pins 519 extend into the corresponding mounting holes 110 of the data storage device 100.

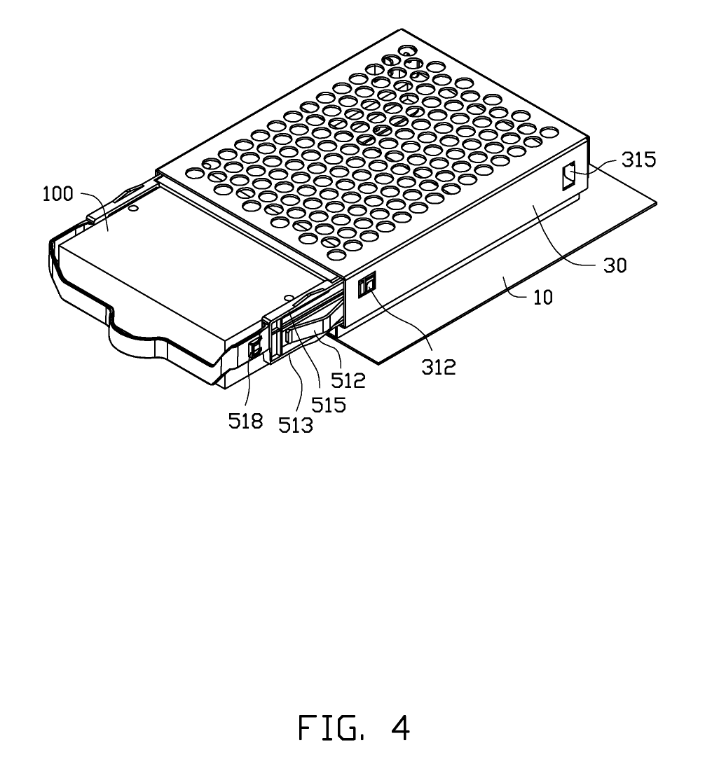

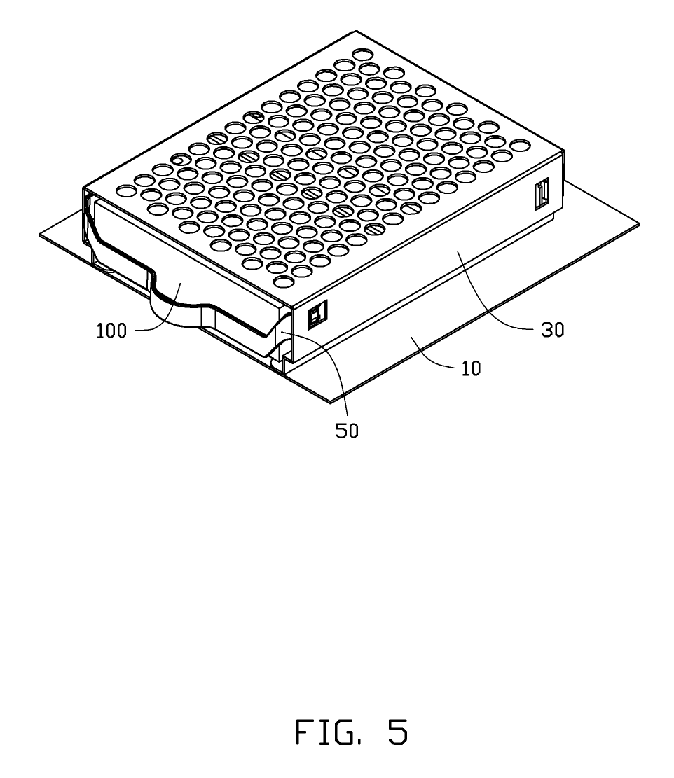

Referring to FIG. 4 and FIG. 5, when assembling the tray 50 with the data storage device 100 into the bracket 30, an end of the tray 50 is moved into the receiving space 39. The springs 512 resiliently abut against the sidewalls 31. The first arms 515 resiliently abut against the top wall 35. The second arms 513 resiliently abut against the supporting flange 331. When the tray 50 is totally moved into the bracket 30, the stops 315 block the tray 50 from further moving any further, and the tabs 518 are engaged with the corresponding locking holes 312.

When vibration is generated by other components 35 and transferred to the bracket 30, the first arm 515 and the second arm 513 can absorb the vibrations along a vertical direction, and the springs 512 can absorb the vibrations along a horizontal direction.

It is also understood, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A retaining apparatus for a data storage device, comprising:
a base board;
a bracket mounted to the base board, a receiving space being defined between the base board and the bracket; and
a tray received in the receiving space, the tray comprising a pair of mounting members, each of the pair of mounting members comprising a spring and an arm;
wherein the spring resiliently abuts the bracket towards a first direction, the arm resiliently abuts the bracket towards a second direction, and the first direction is substantially perpendicular to the second direction.

2. The retaining apparatus of claim 1, wherein the spring comprises a free distal end, and the spring is V-shaped or U-shaped.

3. The retaining apparatus of claim 2, wherein each of the pair of the mounting members comprises a tab, a locking hole is defined in the bracket corresponding to the tab, and the tab is adjacent to the free distal end of the spring.

4. The retaining apparatus of claim 1, wherein the arm is resilient deformed at a middle portion thereof, and the arm comprises a protrusion abutting on the bracket.

5. The retaining apparatus of claim 4, wherein the arm comprises a first arm and a second arm, a first opening is defined in each of the pair of mounting members for providing a first deformation space for the first arm, a second opening is defined in each of the pair of mounting members for providing a second deformation space for the second arm, and the spring is received in the first opening or the second opening.

6. The retaining apparatus of claim 1, wherein the tray further comprises a bridge connecting the pair of mounting members, and a pin is defined in each of the pair of mounting members for retaining the data storage device.

7. The retaining apparatus of claim 6, wherein the tray further comprises a resilient handle connected to the pair of mounting members.

8. The retaining apparatus of claim 1, wherein the bracket comprises two parallel side walls and a top wall, and the spring abuts each of the two side walls.

9. The retaining apparatus of claim 8, wherein the bracket further comprises a step like retaining portion, the retaining portion is mounted on the base board, and the retaining portion comprises a supporting flange for supporting the tray, and each of the pair of mounting members comprises a first arm abutting the top wall and a second arm abutting the supporting flange.

10. The retaining apparatus of claim 8, wherein a plurality of dissipating holes are defined in the top wall.

11. A tray for mounting a data storage device to a bracket, comprising:
a pair of mounting members, each of the pair of mounting members comprising a spring and an arm, the arm being mounted at two opposite ends of the arm and being resilient deformed at a middle portion of the arm; and
a resilient handle connecting the pair of mounting members;
wherein the spring resiliently protrudes towards a first direction, and the arm protrudes towards a second direction, and the first direction is substantially perpendicular to the second direction.

12. The tray of claim 11, wherein the spring comprises a free distal end, and the spring is V-shaped or U-shaped.

13. The tray of claim 12, wherein each of the pair of the mounting members comprises a tab, and the tab being adjacent to the free distal end of the spring.

14. The tray of claim 13, wherein the tab is located adjacent to the resilient handle.

15. The tray of claim 11, wherein the arm comprises a protrusion protruding towards the second direction.

16. The tray of claim 15, wherein the arm comprises a first arm and a second arm, a first opening is defined in each of the pair of mounting members for providing deformation space for the first arm, a second opening is defined in each of the pair of mounting members for providing deformation space for the second arm, and the spring is received in the first opening or the second opening.

17. The tray of claim 11, wherein the tray further comprises a bridge connecting the pair of mounting members, and a pin is defined in each of the pair of the mounting members for retaining the data storage device.
